(19) United States
(12) Patent Application Publication
(10) Pub. No.: US 2026/0114096 A1
(43) Pub. Date: Apr. 23, 2026

(54) LIGHT-EMITTING SUBSTRATE AND DISPLAY DEVICE

(71) Applicant: HKC CORPORATION LIMITED, Shenzhen (CN)

(72) Inventors: YUANGANG HU, Shenzhen (CN); Haijiang Yuan, Shenzhen (CN)

(21) Appl. No.: 19/342,689

(22) Filed: Sep. 29, 2025

(30) Foreign Application Priority Data
Oct. 23, 2024 (CN) 202411492718.7

(51) Int. Cl. H10H 29/24; H01L 25/075; H10H 29/85; H10H 29/855; H10H 29/856

(52) U.S. Cl. CPC H10H 29/24; H10H 29/855; H10H 29/857; H10W 90/00; H10H 29/856

(57) ABSTRACT

The light-emitting substrate includes at least two light boards, an array of a plurality of light-emitting units is arranged on each of the at least two light boards, the light-emitting substrate further includes a splicing assembly disposed between two adjacent light boards, the splicing assembly includes a splicing portion, a first optical portion, and a second optical portion, the first optical portion and the second optical portion are respectively connected to two sides of the splicing portion proximal to the light boards, and both the first optical portion and the second optical portion are located on a light-exiting surface side of the light boards, the splicing portion forms accommodating cavities on sides corresponding to the two adjacent light boards, side edges of the light boards are embedded in the accommodating cavities, and a top surface of the splicing portion covers a seam area between the two adjacent light boards.

### CROSS REFERENCE TO RELATED APPLICATIONS

This application claims the priority and benefit of Chinese patent application number 2024114927187, titled “Light-Emitting Substrate and Display Device” and filed Oct. 23, 2024 with China National Intellectual Property Administration, the entire contents of which are incorporated herein by reference.

### TECHNICAL FIELD

The present disclosure relates to the technical field of display, and particularly to a light-emitting substrate and a display device.

### BACKGROUND

The statements herein provide background information related to the present disclosure but do not necessarily constitute the prior art.

When large-sized display panels employ Mini LEDs as light-emitting elements, manufacturing process difficulties and yield issues prevent the integration of thousands or tens of thousands of light-emitting units onto a single light board. Consequently, multiple light boards are required to be spliced to achieve large dimensions.

However, in such light-emitting substrates, adjacent light boards inherently create seam areas between them. Due to circuit design constraints, the multiple light-emitting units on each light board maintain a certain distance from the seam areas, resulting in the light from these units being unable to illuminate the seam areas. This causes dark shadows to form in the seam regions of the light-emitting substrate, significantly degrading display quality.

Therefore, how to mitigate the shadowing effects in the seam areas of light-emitting substrates has become an urgent technical problem requiring resolution in the field.

### SUMMARY

Embodiments of the present disclosure provide a light-emitting substrate and a display device, aiming to mitigate shadowing effects in seam areas of the light-emitting substrate and enhance display performance.

Disclosed in an embodiment of the present disclosure is a light-emitting substrate, including at least two light boards, an array of a plurality of light-emitting units is arranged on each of the at least two light boards, in which the light-emitting substrate further includes a splicing assembly disposed between two adjacent light boards. The splicing assembly includes a splicing portion, a first optical portion, and a second optical portion, the first optical portion and the second optical portion are respectively connected to two sides of the splicing portion proximal to the light boards, and both the first optical portion and the second optical portion are configured to be located on a light-exiting surface side of the light boards. The splicing portion forms accommodating cavities on sides corresponding to the two adjacent light boards, side edges of the light boards are embedded in the accommodating cavities, and a top surface of the splicing portion covers a seam area between the two adjacent light boards. The first optical portion and the second optical portion are configured to refract light from the plurality of light-emitting units to the seam area.

The embodiments further disclose a display device including a backplate, in which the display device includes the aforementioned light-emitting substrate, and the backplate encases the light-emitting substrate.

The present disclosure improves the light-emitting substrate by arranging a splicing assembly between two adjacent light boards. The splicing portion of the splicing assembly enables mutual splicing of two adjacent light boards. When it is required to splice two adjacent light boards, two adjacent light boards are simply inserted into accommodating cavities of the splicing portion to achieve interconnection therebetween. The top surface of the splicing portion covers the seam area between two adjacent light boards. When light emitted from the plurality of light-emitting units of a side of the light board proximal to the splicing assembly passes through the first optical portion and the second optical portion, the first optical portion and the second optical portion refract and reflect the light toward the splicing portion. The light path of rays unable to reach the seam area is redirected by employing the first optical portion and the second optical portion, ensuring full illumination coverage over the seam area. Consequently, shadowing effects in the seam area of the light-emitting substrate are effectively reduced, significantly improving display quality.

### BRIEF DESCRIPTION OF THE DRAWINGS

The accompanying drawings, which are incorporated in and constitute a part of the specification, provide further understanding of the embodiments of the present disclosure. The drawings illustrate implementations of the present disclosure and, together with the textual description, explain the principles of the present disclosure. It is apparent that the accompanying drawings in the following description merely show some embodiments of the present disclosure. For persons of ordinary skill in the art, other drawings may be derived from these figures without creative efforts. In the drawings:

FIG. 1 is a top view of a first embodiment of the light-emitting substrate according to the present disclosure;

FIG. 2 is a schematic diagram illustrating a splicing assembly connected to two adjacent light boards in the first embodiment of the light-emitting substrate according to the present disclosure;

FIG. 3 is a schematic diagram illustrating the splicing assembly connected to two adjacent light boards in a second embodiment of the light-emitting substrate according to the present disclosure;

FIG. 4 is a schematic diagram illustrating the splicing assembly connected to two adjacent light boards in a third embodiment of the light-emitting substrate according to the present disclosure;

FIG. 5 is a schematic diagram illustrating the splicing assembly connected to two adjacent light boards in a fourth embodiment of the light-emitting substrate according to the present disclosure;

FIG. 6 is a schematic diagram illustrating the splicing assembly connected to two adjacent light boards in a fifth embodiment of the light-emitting substrate according to the present disclosure;

FIG. 7 is a schematic diagram of an embodiment of the display device according to the present disclosure.

### DETAILED DESCRIPTION OF EMBODIMENTS

The following describes the present disclosure in detail with reference to the accompanying drawings and optional embodiments. It should be noted that, under the premise of no conflict, the described embodiments or technical features may be arbitrarily combined to form new embodiments.

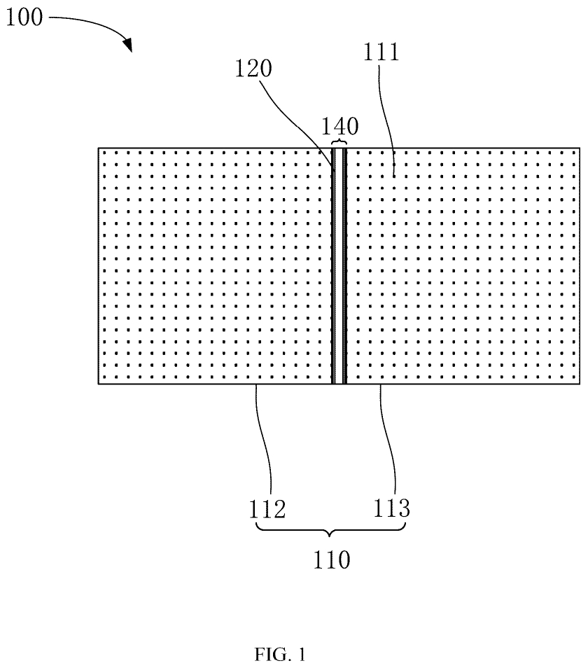

FIG. 1 is a schematic diagram of a first embodiment of the light-emitting substrate according to the present disclosure. FIG. 2 is a schematic diagram illustrating a splicing assembly connected to two adjacent light boards in the first embodiment. As shown in FIGS. 1 and 2, the light-emitting substrate 100 disclosed in the embodiment of the present disclosure includes at least two light boards 110, an array of the plurality of light-emitting units 111 is arranged on each of the at least two light boards 110, a splicing assembly 120 is disposed between two adjacent light boards 110, the splicing assembly 120 includes a splicing portion 121, a first optical portion 130, and a second optical portion 131, the first optical portion 130 and the second optical portion 131 are respectively connected to two sides of the splicing portion 121 proximal to the light boards 110, both the first optical portion 130 and the second optical portion 131 are configured to be located on a light-exiting surface side of the light boards 110, the splicing portion 121 forms accommodating cavities 122 on sides corresponding to the two adjacent light boards 110, side edges of the light boards 110 are embedded in the accommodating cavities 122, a top surface of the splicing portion 121 covers a seam area 140 between the two adjacent light boards 110, and the first optical portion 130 and the second optical portion 131 are configured to refract light emitted from the plurality of light-emitting units 111 toward the seam area 140.

It should be noted that, in FIG. 2, “a” denotes light rays emitted from the plurality of light-emitting units, which are incident on the first optical portion or the second optical portion and undergo refraction.

The present disclosure improves the light-emitting substrate 100 by arranging a splicing assembly 120 between adjacent light boards 110. The splicing portion 121 of the splicing assembly 120 enables mutual splicing of two adjacent light boards 110. When it is required to splice two adjacent light boards 110, two adjacent light boards 110 are simply inserted into accommodating cavities 122 of the splicing portion 121 to achieve interconnection therebetween. The top surface of the splicing portion 121 covers the seam area 140 between two adjacent light boards 110. When light emitted from the plurality of light-emitting units 111 proximal to the splicing assembly 120 passes through the first optical portion 130 and the second optical portion 131, the first optical portion 130 and the second optical portion 131 refract and reflect the light toward the splicing portion 121. The light path of rays unable to reach the seam area 140 is redirected by employing the first optical portion 130 and the second optical portion 131, ensuring full illumination coverage over the seam area 140. Consequently, shadowing effects in the seam area 140 of the light-emitting substrate 100 are effectively reduced, significantly improving display quality.

It should be noted that the light-emitting substrate 100 of the present disclosure is primarily designed for Mini LED light boards, but it is not limited to Mini LED light boards. Other types of light boards with multiple light-emitting units 111, such as Micro LED light boards, are equally applicable. The present disclosure employs Mini LED light boards solely for illustrative purposes.

When implementing ultra-thin, high-brightness, multi-zone displays using Mini-LEDs as light source devices coupled with liquid crystal panels, increasing the number of partitions concurrently elevates the requirements for zonal control. Consequently, the Active Matrix (AM) driving method has been proposed. In AM-driven architectures where external circuits are implemented through direct bonding of driver chips onto the display panel, the plurality of light-emitting units on the source side are positioned farther from the edges of the light boards compared to those in other areas. This configuration creates a scenario where the spacing between plurality of light-emitting units in the seam area exceeds the intra-panel light-emitting unit spacing. During splicing operations, due to this increased inter-unit distance, light emitted from the plurality of light-emitting units is unable to adequately illuminate the seam area, resulting in shadowing phenomena within the seam area.

To address the aforementioned issues, the present disclosure arranges the splicing assembly 120 in the seam area 140 between adjacent light boards 110. The splicing assembly 120 not only interconnects the adjacent light boards 110 but also covers the seam area 140. Through the first optical portion 130 and the second optical portion 131, the light path of rays unable to reach the seam area 140 is redirected, ensuring illumination coverage over the seam area 140, thereby resolving shadowing issues in the seam area 140.

Specifically, the two adjacent light boards 110 include a first light board 112 and a second light board 113. The splicing portion 121 includes a first support portion 123, a second support portion 124, and a third support portion 125. The first support portion 123 is disposed opposite to the third support portion 125, with the first support portion 123 positioned on the light-exiting surface side of the light boards 110. The second support portion 124 is located between the first support portion 123 and the third support portion 125, connected to both the first support portion 123 and the third support portion 125, partitioning the space between the first support portion 123 and the third support portion 125 to form the accommodating cavities 122. The first optical portion 130 is disposed on a side of the first support portion 123 proximal to the first light board 112, while the second optical portion 131 is disposed on a side of the first support portion 123 proximal to the second light board 113.

In this embodiment, the splicing portion 121 is an integrally formed structure. The splicing portion 121 may adopt an I-shaped configuration including the first support portion 123, second support portion 124, and third support portion 125, with the accommodating cavities 122 being formed on both lateral sides of the I-shaped structure.

When splicing two adjacent light boards 110, simply insert the two adjacent light boards 110 into the accommodating cavities 122 on both sides of the splicing portion 121. The first support portion 123 and the third support portion 125 respectively abut against the two adjacent light boards 110, securing the light boards 110 being embedded within the accommodating cavities 122. This configuration completes the splicing assembly of adjacent light boards 110, achieving simple and convenient installation.

When light emitted from plurality of light-emitting units 111 of a side of the light board 110 proximal to the splicing assembly 120 passes through the first optical portion 130 and the second optical portion 131, the first optical portion 130 and the second optical portion 131 refract and reflect the light toward the splicing portion 121. The light path of rays unable to reach the seam area 140 is redirected by employing the first optical portion 130 and the second optical portion 131, ensuring full illumination coverage over the seam area 140. Consequently, shadowing effects in the seam area 140 of the light-emitting substrate 100 are effectively reduced, significantly improving display quality.

To ensure light emitted from the plurality of light-emitting units 111 is able to illuminate the first optical portion 130 and the second optical portion 131, and that the first optical portion 130 and the second optical portion 131 refract the light toward the seam area 140 after transmission, the present disclosure implements the following designs for the first optical portion 130 and the second optical portion 131:

The first optical portion 130 and the second optical portion 131 are each tilted toward the light boards 110 at a predetermined angle α, where α is less than or equal to 60°.

This inclined orientation that the first optical portion 130 and the second optical portion 131 are each tilted toward the light boards 110 allows the first optical portion 130 and the second optical portion 131 to efficiently capture oblique light rays emitted from the plurality of light-emitting units 111.

Furthermore, in Mini LED configurations, the plurality of light-emitting units 111 at the outermost edges typically exhibit a light-exiting angle of 30°. According to the triangle angle sum theorem (summing to 180°), the incident light received by the first optical portion 130 and the second optical portion 131 must not be perpendicular to their inclined surfaces, as this would prevent refraction.

If the tilt angle between the first/second optical portions 130/131 and the light boards 110 exceeds 60°, the resulting refraction angle increases, causing the convergence point of refracted light to shift toward the display panel. This induces expanded haloing effects and enlarged dark zones. Therefore, the present disclosure sets an angle formed by inclining the first optical portion 130 and the second optical portion 131 relative to the light board 110 to be less than or equal to 60°. This configuration allows oblique light rays emitted from the plurality of light-emitting units 111 to more readily irradiate the first optical portion 130 and the second optical portion 131. Simultaneously, the light rays irradiating the first optical portion 130 and the second optical portion 131 undergo refraction, with the refracted light direction oriented toward the interior of the seam area 140, thereby effectively mitigating shadow issues in the seam area 140.

In some embodiments, according to the present disclosure, the splicing assembly 120 is made of transparent material, or only the first optical portion 130 and second optical portion 131 are made of transparent material. For example, the splicing assembly 120, the first optical portion 130, or the second optical portion 131 may be fabricated from glass or transparent resin materials. This configuration enables normal light transmission when light rays emitted from the plurality of light-emitting units 111 irradiate the first optical portion 130 and the second optical portion 131, allowing refraction to occur by means of the first optical portion 130 and the second optical portion 131. The first optical portion 130 and the second optical portion 131 thereby alter the light path to direct adjusted light toward the seam area 140, effectively addressing shadow issues in the seam area 140. When the entire splicing assembly 120 is fabricated from transparent materials, a single transparent material may be employed, simplifying manufacturing processes, facilitating production, and achieving cost efficiency.

It should be noted that the width of the overlapping portion between the splicing assembly 120 and the seam area 140 formed between two adjacent light boards 110 may be adaptively designed according to the dimensions of the seam area 140. The width may be set to 0.5 mm to facilitate assembly operations.

Additionally, the height of the portions of the first optical portion 130 and the second optical portion 131 protruding from the light board 110 should satisfy the condition that the center point of the top surface of the splicing portion 121 is lower than the maximum light emission angle extension lines of the plurality of light-emitting units 111 on two adjacent light boards 110. As shown in FIG. 1, this configuration reserves space for the intersection point of refracted light rays when the focal point of the light ray extension lines is higher than the center position of the top surface of the splicing portion 121, thereby facilitating light coverage over the seam area 140.

In some embodiments, to ensure that the first optical portion 130 and the second optical portion 131 are able to effectively receive light rays emitted from the plurality of light-emitting units 111 and thereby optimally process such light, the present disclosure further provides specific designs for the first optical portion 130 and the second optical portion 131, as detailed below:

An edge of the first light board 112 proximal to the first optical portion 130 is provided with a plurality of first light-emitting units 114; an edge of the second light board 113 proximal to the second optical portion 131 is provided with a plurality of second light-emitting units 115. An orthographic projection of the first optical portion 130 on the first light board 112 partially overlaps orthographic projections of the plurality of first light-emitting units 114 on the first light board 112, and an orthographic projection of the second optical portion 131 on the second light board 113 partially overlaps orthographic projections of the plurality of second light-emitting units 115 on the second light board 113.

Since light rays emitted from the plurality of light-emitting units 111 closest to the first optical portion 130 and the second optical portion 131 on the light board 110 are more readily received by the first optical portion 130 and the second optical portion 131, the first optical portion 130 and the second optical portion 131 are inclined toward the first light board 112 and the second light board 113, respectively. The first optical portion 130 and the second optical portion 131 partially occlude the first light-emitting unit 114 located at the edge of the first light board 112 and the second light-emitting unit 115 located at the edge of the second light board 113, respectively. This configuration allows light rays emitted from the first light-emitting unit 114 and the second light-emitting unit 115 to more easily irradiate the first optical portion 130 and the second optical portion 131. Consequently, the first optical portion 130 and the second optical portion 131 are able to alter the light path to direct adjusted light toward the seam area 140, thereby resolving shadow issues in the seam area 140 while avoiding adverse impacts on normal light emission performance of the plurality of light-emitting units 111 caused by complete occlusion of the first light-emitting unit 114 or the second light-emitting unit 115.

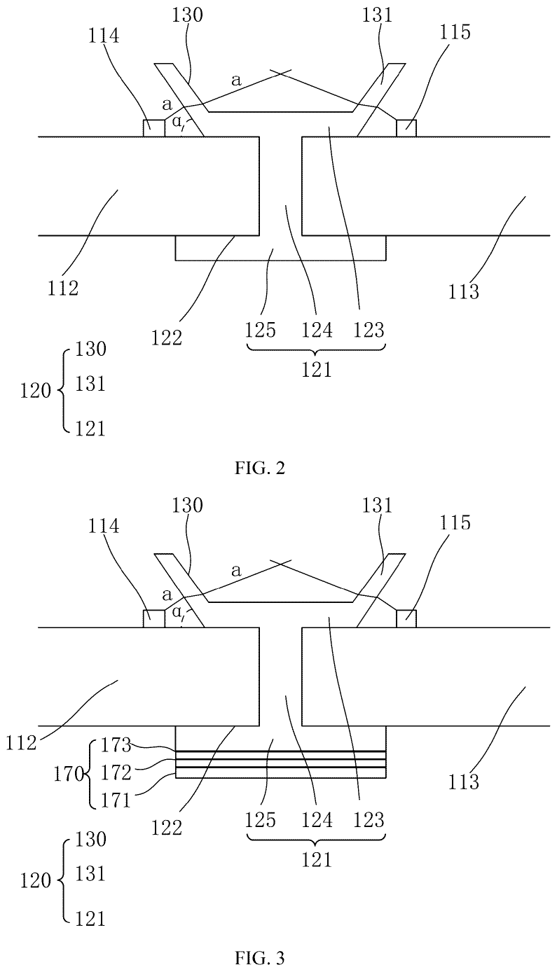

FIG. 3 illustrates a schematic diagram of a splicing assembly interconnected with two adjacent light boards in a second embodiment of the light-emitting substrate according to the present disclosure. As shown in FIG. 3, this embodiment constitutes an improvement based on FIG. 2.

The splicing assembly 120 is made of glass, a light-emitting assembly 170 is disposed at a bottom of the splicing assembly 120, the light-emitting assembly 170 includes a first substrate 171, a drive circuit layer 172 is disposed 171 above the first substrate 171, a light-emitting element 173 is disposed on the drive circuit layer 172, and the drive circuit layer 172 is electrically connected to the light-emitting element 173 and configured to drive the light-emitting element 173 to emit light.

The present embodiment differs from the embodiment shown in FIG. 2 in that the splicing assembly 120 is integrally fabricated from a glass material, providing superior light transmittance. Additionally, a light-emitting assembly 170 is disposed at the bottom of the splicing assembly 120. The drive circuit layer 172 of the light-emitting assembly 170 may be formed on the first substrate 171 through processes such as etching and deposition. The drive circuit layer 172 is configured to control the light-emitting element 173 to emit light.

When the luminous flux within the seam area 140 is insufficient, the drive circuit layer 172 may be controlled to activate the light-emitting element 173. The light emitted from the light-emitting element 173 transmits through the glass-made splicing assembly 120, thereby supplementing the luminous flux in the seam area 140. This mechanism proactively addresses low brightness and shadow issues in the seam area 140 by actively enhancing illumination within the seam area 140.

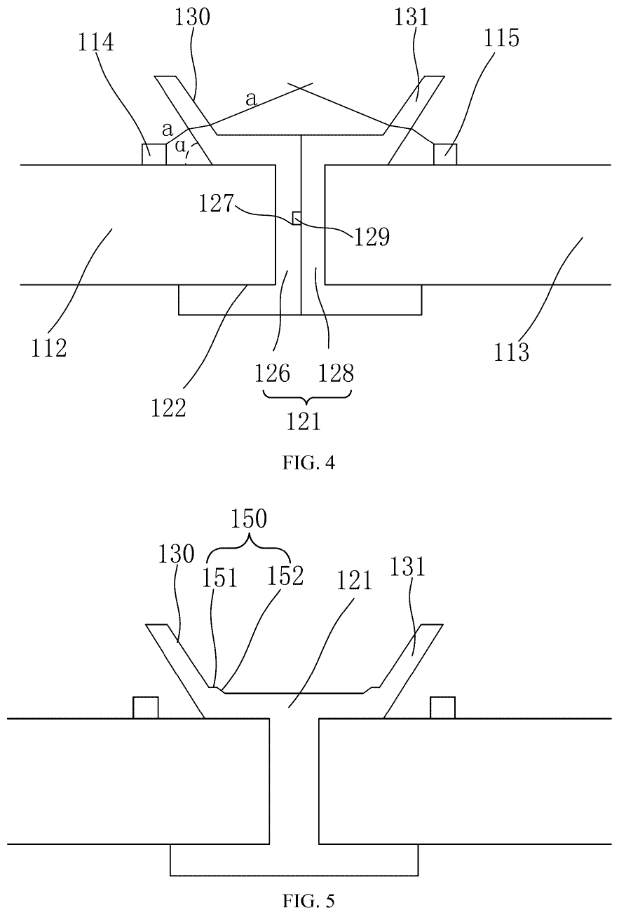

FIG. 4 illustrates a schematic diagram of a splicing assembly interconnected with two adjacent light boards in a third embodiment of the light-emitting substrate according to the present disclosure. As shown in FIG. 4, the two adjacent light boards 110 include a first light board 112 and a second light board 113, the splicing portion 121 includes a first splicing portion 126 and a second splicing portion 128, the first optical portion 130 is connected to a side of the first splicing portion 126 proximal to the first light board 112, the second optical portion 131 is connected to a side of the second splicing portion 128 proximal to the second light board 113, and a side of the first splicing portion 126 distal to the first light board 112 is spliced to a side of the second splicing portion 128 distal to the second light board 113; the first splicing portion 126 is provided with one of the accommodating cavities 122 at a position corresponding to the first light board 112, and the second splicing portion 128 is provided with one of the accommodating cavities 122 at a position corresponding to the second light board 112.

The present embodiment differs from the preceding embodiment in that the splicing portion 121 includes two independent components, i.e., a first splicing portion 126 and a second splicing portion 128. The first optical portion 130 is connected to the first splicing portion 126, while the second optical portion 131 is connected to the second splicing portion 128. This configuration forms one splicing member through the combination of the first optical portion 130 and the first splicing portion 126, and another splicing member through the combination of the second optical portion 131 and the second splicing portion 128.

When splicing two adjacent light boards 110, one light board 110 is embedded into the accommodation cavity 122 of the first splicing portion 126, and the other light board 110 is embedded into the accommodation cavity 122 of the second splicing portion 128. The first splicing portion 126 and the second splicing portion 128 are then joined together, completing the splicing of the two adjacent light boards 110.

When light emitted from plurality of light-emitting units 111 of a side of the light board 110 proximal to the splicing assembly 120 passes through the first optical portion 130 and the second optical portion 131, the first optical portion 130 and the second optical portion 131 refract and reflect the light toward the splicing portion 121. The light path of rays unable to reach the seam area 140 is redirected by employing the first optical portion 130 and the second optical portion 131, ensuring full illumination coverage over the seam area 140. Consequently, shadowing effects in the seam area 140 of the light-emitting substrate 100 are effectively reduced, significantly improving display quality.

In some embodiments, a first connection portion 127 is disposed on the side of the first splicing portion 126 distal to the first light board 112, a second connection portion 129 is disposed at a position of the second splicing portion 128 corresponding to the first connection portion 127, and the first connection portion 127 is connected to the second connection portion 129 to splice the first splicing portion 126 and the second splicing portion 128.

In the present embodiment, since the splicing portion 121 includes two independent structures, after inserting two adjacent light boards 110 into the accommodation cavities 122 of the first splicing portion 126 and the second splicing portion 128 respectively, the first connection portion 127 on the first splicing portion 126 is able to be engaged with the second connection portion 129 on the second splicing portion 128. This enables the first splicing portion 126 and the second splicing portion 128 to be interconnected via the first connection portion 127 and the second connection portion 129, thereby achieving splicing between the two adjacent light boards 110.

The first splicing portion 126 and the second splicing portion 128 may be fixed by magnetic attraction or connected via snap-fit mechanisms, though these examples are non-limiting.

For instance, when magnetic attraction is employed for fixing the first splicing portion 126 and the second splicing portion 128, magnetic strip mounting grooves may be internally provided in both the first splicing portion 126 and the second splicing portion 128. Magnetic strips are asymmetrically arranged in partitioned zones within the grooves. During splicing, misalignment of the magnetic strips prevents complete splicing, whereas proper alignment enables magnetic fixation.

When the first splicing portion 126 and the second splicing portion 128 are fixed via a snap-fit mechanism, corresponding protrusions and latch grooves may be provided on the mating surfaces between the first splicing portion 126 and the second splicing portion 128. During splicing of the first splicing portion 126 and the second splicing portion 128, the protrusions engage with the latch grooves to secure the first splicing portion 126 and the second splicing portion 128, thereby achieving interconnection.

Additionally, to maintain the fixed state of the splicing assembly 120, screw holes may be provided at the bottom of the splicing portion 121 corresponding to the bottom surfaces of the two adjacent light boards 110. Alternatively, an adhesive coating may be applied to connect the bottom of the splicing portion 121 with the bottom of the light boards 110, enhancing connection stability between the splicing assembly 120 and the adjacent light boards 110.

FIG. 5 illustrates a schematic diagram of a splicing assembly interconnected with two adjacent light boards in a fourth embodiment of the light-emitting substrate according to the present disclosure. As shown in FIG. 5, a recessed portion 150 is disposed between the splicing portion 121 and the first optical portion 130, and between the splicing portion 121 and the second optical portion 131, respectively, the recessed portion 150 recessing the splicing portion 121 by a predetermined distance relative to the first optical portion 130 and the second optical portion 131.

The recessed portion 150 includes a first surface 151 and a second surface 152, a side of the second surface 152 is connected to the first surface 151, an opposite side of the second surface 152 extends toward the splicing portion 121 and is connected to a top surface of the splicing portion 121, the first surface 151 is parallel to the top surface of the splicing portion 121, and the second surface 152 is inclined at a predetermined angle relative to the splicing portion 121.

The present embodiment differs from the preceding embodiment in that recessed portions 150 are additionally disposed between the splicing portion 121 and the optical portions. The first surface 151 of the recessed portion 150 is parallel to the top surface of the splicing portion 121, while the second surface 152 extends downward toward the splicing portion 121 and is inclined at a predetermined angle relative to the splicing portion 121. This configuration forms a “stepped” structure of the recessed portion 150, positioning the splicing portion 121 lower than the first optical portion 130 and the second optical portion 131 by a preset distance. The top surface of the splicing portion 121 is positioned within the recessed region formed between the two recessed portions 150.

The recessed region serves to create a retention space for uniform mixing of light rays without interference from external media. Furthermore, when the splicing assembly 120 is subjected to compressive loads from a diffuser plate at the recessed portions 150, the structure exhibits enhanced resistance to deformation, fracture, or similar issues, thereby improving the mechanical robustness of the splicing assembly 120.

FIG. 6 illustrates a schematic diagram of a splicing assembly interconnected with two adjacent light boards in a fifth embodiment of the light-emitting substrate according to the present disclosure. As shown in FIG. 6, this embodiment constitutes an improvement based on FIG. 5. The top surface of the splicing portion 121 is provided with a plurality of optical structures 160, and the optical structures 160 are designed to reflect or refract light rays.

It should be noted that in FIG. 5, a denotes the light path of rays emitted from the plurality of light-emitting units, which irradiate the first optical portion or the second optical portion and undergo refraction; b denotes the light path of a portion of rays emitted from the plurality of light-emitting units, which refract toward the display panel and are subsequently reflected onto the optical structures; c denotes the light path of rays reflected by the optical structures.

The present embodiment differs from the preceding embodiment in that the plurality of optical structures 160 are disposed on the top surface of the splicing portion 121. The plurality of optical structures 160 may be formed on the top surface of the splicing portion 121 through any one of the following texturization processes: coating, microdot spraying, or film lamination. Alternatively, the plurality of optical structures 160 may be lens structures disposed on the top surface of the splicing portion 121.

It is understandable that light rays are emitted from the plurality of light-emitting units 111 on a side of the light board 110 proximal to the splicing assembly 120, a portion of oblique rays irradiate the first optical portion 130 and the second optical portion 131, while a portion of collimated light rays irradiate optical films, diffuser plates, or similar materials within the display module.

Based on the aforementioned light propagation paths, the present embodiment processes light through at least two primary mechanisms by disposing optical structures 160 on the top surface of the splicing portion 121:

First mechanism: when a portion of light irradiates the first optical portion 130 and the second optical portion 131, the first optical portion 130 and the second optical portion 131 perform initial refraction and reflection on the light. The first optical portion 130 and the second optical portion 131 modify the light path during this first-stage alteration. The light subsequently transmits through the first optical portion 130 and the second optical portion 131 and irradiates the optical structures 160 on the top surface of the splicing portion 121. The optical structures 160 then induce a secondary alteration of the light path of the light irradiated from the first optical portion 130 and the second optical portion 131, further distributing the light across the entire top surface of the splicing portion 121, thereby achieving coverage over the seam area 140.

Second mechanism: when the light-emitting unit 111 emitting light reflected from optical films, diffuser plates, or similar materials in the display module irradiates the optical structures 160, the optical structures 160 modify the secondary irradiation path. A portion of light rays at effective angles are blended within the seam area 140, ensuring comprehensive illumination coverage across the entire seam area 140.

In essence, the coordinated operation of the first optical portion 130, the second optical portion 131, and the optical structures 160 synergistically mitigates shadowing effects in the seam area 140 of the light-emitting substrate 100, thereby enhancing display performance.

It should be noted that when the optical structures 160 are configured as diamond-shaped lens structures, the inclined edges of the optical structures 160 may be tilted at a predetermined angle relative to the top surface of the splicing portion 121. For example, the predetermined angle may be set to 25°. Considering that a portion of light rays passing through the diffuser plate within the display panel are reflected, these rays undergo further reflection upon passing through the optical structures 160. When incident light strikes the optical structures 160, the inclined surfaces reflect the light according to optical reflection principles. A larger tilt angle (i.e., smaller incident angle) causes reflected rays to propagate closer to the base layer. However, excessively small incident angles would preclude effective refraction. By setting the inclined edge angle of the optical structures 160 to 25°, optimal light distribution across the entire top surface of the splicing portion 121 is achieved, ensuring comprehensive illumination coverage of the seam area 140 and thereby resolving shadowing issues of the seam area 140.

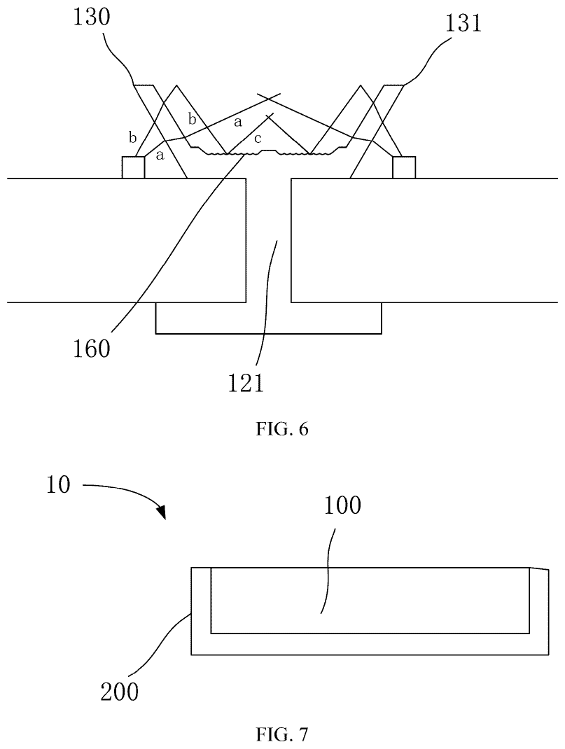

FIG. 7 illustrates a schematic diagram of an embodiment of a display device 10 according to the present disclosure. As shown in FIG. 7, the disclosed display device 10 includes a backplate 200 and incorporates the aforementioned light-emitting substrate 100, with the backplate 200 encapsulating the light-emitting substrate 100. The backplate 200 serves to protect the light-emitting substrate 100 from damage caused by external forces, thereby extending the operational lifespan of the light-emitting substrate 100.

It should be noted that the display device 10 of the present disclosure is not limited to configurations employing Mini LED light boards 110, but may also utilize Micro LED light boards 110. Furthermore, the display device 10 according to the present disclosure may be implemented in large-scale applications such as televisions exceeding 75 inches or conference room display systems, with no specific constraints imposed on the type of the display device 10.

In large-scale display devices 10 employing Mini LED light boards 110, a plurality of light boards 110 are typically spliced to achieve a large-scale light board 110. However, light rays from the plurality of light-emitting units 111 on the light boards 110 fail to adequately illuminate the seam area 140, resulting in shadow issues in the seam area 140 of the light-emitting substrate 100, which compromises display quality.

In view of the aforementioned issues, the present disclosure improves the light-emitting substrate 100 in the display device 10 by arranging a splicing assembly 120 between every two adjacent light boards 110. The splicing portion 121 of the splicing assembly 120 enables mutual splicing of two adjacent light boards 110. When it is required to splice two adjacent light boards 110, two adjacent light boards 110 are simply inserted into accommodating cavities 122 of the splicing portion 121 to achieve interconnection therebetween. The top surface of the splicing portion 121 covers the seam area 140 between two adjacent light boards 110. When light emitted from plurality of light-emitting units 111 of a side of the light board 110 proximal to the splicing assembly 120 passes through the first optical portion 130 and the second optical portion 131, the first optical portion 130 and the second optical portion 131 refract and reflect the light toward the splicing portion 121. The light path of rays unable to reach the seam area 140 is redirected by employing the first optical portion 130 and the second optical portion 131, ensuring full illumination coverage over the seam area 140. Consequently, shadowing effects in the seam area 140 of the light-emitting substrate 100 are effectively reduced, significantly improving display quality, thereby improving the quality of the display device 10.

It should be expressly stated that while the inventive concept of the present disclosure may manifest in numerous embodiments, the specification's page limitations preclude exhaustive enumeration. Accordingly, under a non-conflicting basis, the described embodiments or technical features may be arbitrarily combined to form new embodiments. Such combinations of embodiments or technical features synergistically enhance the original technical effects.

The foregoing detailed description with reference to specific optional embodiments should not be construed as limiting the scope of implementation of the present disclosure. For persons skilled in the art pertinent to this disclosure, routine derivations or substitutions made without departing from the inventive concept shall fall within the protection scope defined by the present disclosure.

What is claimed is:

1. A light-emitting substrate, comprising: at least two light boards, an array of a plurality of light-emitting units is arranged on each of the at least two light boards, wherein the light-emitting substrate further comprises a splicing assembly disposed between every two adjacent light boards;
the splicing assembly comprises a splicing portion, a first optical portion, and a second optical portion, the first optical portion and the second optical portion are respectively connected to two sides of the splicing portion proximal to the light boards, and both the first optical portion and the second optical portion are configured to be located on a light-exiting surface side of the light boards;
the splicing portion forms accommodating cavities on sides corresponding to the two adjacent light boards, side edges of the light boards are embedded in the accommodating cavities, and a top surface of the splicing portion covers a seam area between the two adjacent light boards; and
the first optical portion and the second optical portion are configured to refract light from the plurality of light-emitting units to the seam area.

2. The light-emitting substrate according to claim 1, wherein the first optical portion and the second optical portion are both tilted at a predetermined angle toward the light boards; and the predetermined angle is less than or equal to 60 degrees.

3. The light-emitting substrate according to claim 2, wherein the splicing assembly is made of transparent material, or only the first optical portion and the second optical portion are made of transparent material.

4. The light-emitting substrate according to claim 3, wherein the splicing assembly is made of glass or transparent resin material, or the first optical portion and the second optical portion are made of glass or transparent resin material.

5. The light-emitting substrate according to claim 4, wherein a width of an overlapping portion between the splicing assembly and the seam area of the two adjacent light boards is 0.5 millimeters.

6. The light-emitting substrate according to claim 5, wherein the splicing assembly is made of glass, a light-emitting assembly is disposed at a bottom of the splicing assembly, the light-emitting assembly comprises a first substrate, a drive circuit layer is disposed above the first substrate, a light-emitting element is disposed on the drive circuit layer, and the drive circuit layer is electrically connected to the light-emitting element and configured to drive the light-emitting element to emit light.

7. The light-emitting substrate according to claim 5, wherein the two adjacent light boards comprise a first light board and a second light board, the splicing portion comprises a first support portion, a second support portion, and a third support portion, the first support portion is disposed opposite to the third support portion, the first support portion is located on a light-exiting surface side of the light boards, the second support portion is located between the first support portion and the third support portion, and the second support portion is connected to both the first support portion and the third support portion, and the second support portion divides a space between the first support portion and the third support portion to form the accommodating cavities;
the first optical portion is disposed on a side of the first support portion adjacent to the first light board, and the second optical portion is disposed on a side of the first support portion adjacent to the second light board.

8. The light-emitting substrate according to claim 7, wherein the splicing portion is an integrally formed structure.

9. The light-emitting substrate according to claim 8, wherein the splicing portion has an I-shaped structure.

10. The light-emitting substrate according to claim 3, wherein the two adjacent light boards comprise a first light board and a second light board, the splicing portion comprises a first splicing portion and a second splicing portion, the first optical portion is connected to a side of the first splicing portion proximal to the first light board, the second optical portion is connected to a side of the second splicing portion proximal to the second light board, and a side of the first splicing portion distal to the first light board is spliced to a side of the second splicing portion distal to the second light board;
the first splicing portion is provided with one of the accommodating cavities at a position corresponding to the first light board, and the second splicing portion is provided with one of the accommodating cavities at a position corresponding to the second light board.

11. The light-emitting substrate according to claim 10, wherein a first connection portion is disposed on the side of the first splicing portion distal to the first light board, a second connection portion is disposed at a position of the second splicing portion corresponding to the first connection portion, and the first connection portion is connected to the second connection portion to splice the first splicing portion and the second splicing portion.

12. The light-emitting substrate according to claim 11, wherein the first splicing portion and the second splicing portion are connected through magnetic attraction or snap-fit engagement.

13. The light-emitting substrate according to claim 7, wherein an edge of the first light board proximal to the first optical portion is provided with a plurality of first light-emitting units; an edge of the second light board proximal to the second optical portion is provided with a plurality of second light-emitting units;
an orthographic projection of the first optical portion on the first light board partially overlaps orthographic projections of the plurality of first light-emitting units on the first light board, and an orthographic projection of the second optical portion on the second light board partially overlaps orthographic projections of the plurality of second light-emitting units on the second light board.

14. The light-emitting substrate according to claim 10, wherein an edge of the first light board proximal to the first optical portion is provided with a plurality of first light-emitting units; an edge of the second light board proximal to the second optical portion is provided with a plurality of second light-emitting units;
an orthographic projection of the first optical portion on the first light board partially overlaps orthographic projections of the plurality of first light-emitting units on the first light board, and an orthographic projection of the second optical portion on the second light board partially overlaps orthographic projections of the plurality of second light-emitting units on the second light board.

15. The light-emitting substrate according to claim 11, wherein an edge of the first light board proximal to the first optical portion is provided with a plurality of first light-emitting units; an edge of the second light board proximal to the second optical portion is provided with a plurality of second light-emitting units;
an orthographic projection of the first optical portion on the first light board partially overlaps orthographic projections of the plurality of first light-emitting units on the first light board, and an orthographic projection of the second optical portion on the second light board partially overlaps orthographic projections of the plurality of second light-emitting units on the second light board.

16. The light-emitting substrate according to claim 15, wherein a recessed portion is disposed between the splicing portion and the first optical portion, and between the splicing portion and the second optical portion, respectively, the recessed portion recessing the splicing portion by a predetermined distance relative to the first optical portion and the second optical portion;
the recessed portion comprises a first surface and a second surface, a side of the second surface is connected to the first surface, an opposite side of the second surface extends toward the splicing portion and is connected to a top surface of the splicing portion, the first surface is parallel to the top surface of the splicing portion, and the second surface is inclined at a predetermined angle relative to the splicing portion.

17. The light-emitting substrate according to claim 16, wherein the top surface of the splicing portion is provided with a plurality of optical structures configured to reflect or refract light.

18. The light-emitting substrate according to claim 17, wherein the plurality of optical structures are formed on the top surface of the splicing portion through any one of the following texturization processes: coating, microdot spraying, or film lamination.

19. The light-emitting substrate according to claim 17, wherein the plurality of optical structures are lens structures disposed on the top surface of the splicing portion.

20. A display device, comprising a backplate, wherein the display device further comprises the light-emitting substrate according to claim 1, the backplate encasing the light-emitting substrate.
